(19) United States
(12) Patent Application Publication
(10) Pub. No.: US 2018/0088408 A1
(43) Pub. Date: Mar. 29, 2018

(54) COLOR FILM SUBSTRATE, MANUFACTURING METHO, AND LIQUID CRYSTAL DEVICE

(71) Applicant: Shenzhen China Star Optoelectronics Technology Co., Ltd., Shenzhen, Guangdong (CN)

(72) Inventor: Haijun WANG, Shenzhen, Guangdong (CN)

(73) Assignee: Shenzhen China Star Optoelectronics Technology Co., Ltd., Shenzhen, Guangdong (CN)

(21) Appl. No.: 15/031,742

(22) PCT Filed: Apr. 8, 2016
(86) PCT No.: PCT/CN2016/078797

§ 371 Date: Apr. 24, 2016

(30) Foreign Application Priority Data
Mar. 24, 2016 (CN) 201610176754.1

(51) Int. Cl. G02F 1/1335; G03F 7/00

(52) U.S. Cl. CPC G02F 1/133516; G03F 7/0007; G02F 1/133528

(57) ABSTRACT

The present disclosure relates to a color filter (CF) substrate and the manufacturing method thereof, and a liquid crystal device (LCD). The CF substrate includes a quantum dots/PFA layer. The manufacturing method includes mixing quantum dots with PFA material and coating the material on the substrate, adopting a mask to expose the quantum dots and the PFA materials, and applying a developing process to obtain a quantum dots/PFA layer having an offset structure, and coating a CF layer on the quantum dots/PFA layer. By configuring the quantum dots/PFA layer on the CF substrate, the brightness of the backlight, the color saturation, and the color range may be enhanced.

### BACKGROUND OF THE INVENTION

### 1. Field of the Invention

The present disclosure relates to flat display technology, and more particularly to a color filter (CF) substrate and the manufacturing method thereof, and a liquid crystal device (LCD).

2. Discussion of the Related Art

With respect to TFT-LCD technology, CF film is a key component for converting the backlight to RGB colors. Currently, most of the backlight are white. However, although the color range of the LED backlight is high, but the brightness is low. Thus, the number of LEDs has to be increased to enhance the brightness. This may results in higher power consumption and higher cost, and thus other solution has to be developed.

### SUMMARY

The present disclosure relates to a CF substrate and the manufacturing method thereof, and a LCD. With the proposed configuration, the brightness of the backlight may be enhanced, which results in a better color saturation and color range of the liquid crystal panel.

In one aspect, a manufacturing method of color filter (CF) substrate includes: providing a substrate; mixing quantum dots with PFA material and coating the material on the substrate, wherein the quantum dots include red (R), green (G), and blue (B) quantum dots; adopting a mask to expose the quantum dots and the PFA materials, and applying a developing process to obtain a quantum dots/PFA layer having an offset structure; and coating a CF layer on the quantum dots/PFA layer, wherein the CF layer includes a red (R) photo-resist layer, a green (G) photo-resist layer and a blue (B) photo-resist layer, and the R photo-resist layer, the G photo-resist layer, and the B photo-resist layer are formed to be above the quantum dots/PFA layer and to be adjacent in turn.

Wherein a thickness of the R photo-resist layer is the same with the thickness of the G photo-resist layer, and the thickness of the B photo-resist layer is larger than the thickness of the R photo-resist layer or the G photo-resist layer for 0.1-0.5 um.

Wherein after the step of coating a CF layer on the quantum dots/PFA layer, the method further includes: forming a polarized layer on the CF layer; forming an ITO layer on the polarized layer; and forming a PI layer on the ITO layer.

In another aspect, a CF substrate includes: a substrate; a quantum dots/PFA layer formed on the substrate; a CF layer formed on the quantum dots/PFA layer; and wherein the quantum dots include red (R), green (G), and blue (B) quantum dots, the CF layer includes a red (R) photo-resist layer, a green (G) photo-resist layer and a blue (B) photo-resist layer, and the R photo-resist layer, the G photo-resist layer, and the B photo-resist layer are formed to be above the quantum dots/PFA layer and to be adjacent in turn.

Wherein a thickness of the R photo-resist layer is the same with the thickness of the G photo-resist layer, and the thickness of the B photo-resist layer is larger than the thickness of the R photo-resist layer or the G photo-resist layer for 0.1-0.5 um.

Wherein the CF substrate further includes: a polarized layer on the CF layer; an ITO layer on the polarized layer; and a PI layer on the ITO layer.

In another aspect, a liquid crystal device (LCD) includes: a CF substrate, an array substrate, a backlight module, and liquid crystals between the array substrate and the CF substrate, the CF substrate includes: a first substrate; a quantum dots/PFA layer formed on the first substrate; a CF layer formed on the quantum dots/PFA layer; and wherein the quantum dots include red (R), green (G), and blue (B) quantum dots, the CF layer includes a red (R) photo-resist layer, a green (G) photo-resist layer and a blue (B) photo-resist layer, and the R photo-resist layer, the G photo-resist layer, and the B photo-resist layer are formed to be above the quantum dots/PFA layer and to be adjacent in turn.

Wherein a thickness of the R photo-resist layer is the same with the thickness of the G photo-resist layer, and the thickness of the B photo-resist layer is larger than the thickness of the R photo-resist layer or the G photo-resist layer for 0.1-0.5 um.

Wherein the CF substrate further includes: a first polarized layer formed on the CF layer; a first ITO layer formed on the first polarized layer; and a first PI layer formed on the first ITO layer.

Wherein the array substrate further includes: a second substrate; a second polarized layer formed on the second substrate; a second ITO formed on a surface of the second substrate facing away the second polarized layer; a second PI layer below the second ITO layer; and the liquid crystals are arranged between the first PI layer and the second PI layer.

In view of the above, the quantum dots/PFA layer is configured on the CF substrate, and the CF layer is configured on the quantum dots/PFA layer having the offset structure. In this way, the backlight brightness may be enhanced. In addition, the power consumption and the cost may be saved so as to enhance the color saturation and the color range of the liquid crystal panel.

### BRIEF DESCRIPTION OF THE DRAWINGS

FIG. 1 is a flowchart of the manufacturing method of the CF substrate in accordance with one embodiment.

FIG. 2 is a schematic view of the CF substrate of FIG. 1.

FIG. 3 is a schematic view of the LCD in accordance with one embodiment.

### DETAILED DESCRIPTION OF THE EMBODIMENTS

Embodiments of the invention will now be described more fully hereinafter with reference to the accompanying drawings, in which embodiments of the invention are shown.

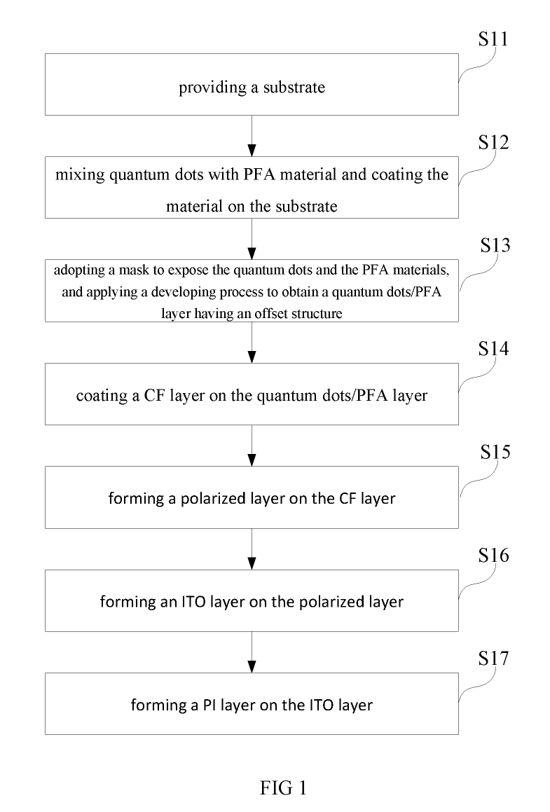

FIG. 1 is a flowchart of the manufacturing method of the CF substrate in accordance with one embodiment. The method includes the following steps.

In step S11, providing a substrate 11.

The substrate 11 may be, but not limited to, a glass or quartz substrate.

In step S12, mixing quantum dots and PFA material and coating the material on the substrate 11.

Wherein the quantum dots includes red (R), green (G), and blue (B) quantum dots. The quantum dots are nanoscale materials, and are self-luminescent. When being activated by light, the quantum dots may emit lights of three colors. The peak width at half height of such light is smaller, and the purity is higher. The brightness and the purity of the white light obtained after being mixed may be greatly enhanced, when compared to the conventional backlight. PFA relates to Polyfluoroalkoxy. In the embodiment, the R quantum dots, the G quantum dots, the B quantum dots, and the PFA materials are mixed according to a certain ratio to obtain the quantum dot compound.

A spin-coating method or slit coating method may be adopted to coating the quantum dot compound on the substrate 11. Usually, the particle diameter of the R quantum dots and the G quantum dots may be in a range between 1 and 10 nm, and the particle diameter of the brightness quantum dots may be under 5 nm.

In step S13, adopting a mask to expose the quantum dots and the PFA materials, and applying a developing process to obtain a quantum dots/PFA layer 12 having an offset structure.

Before coating the quantum dot compound on the substrate 11, black matrices (now shown) have to be configured on the substrate 11, and the black matrices are spaced apart from each other. The black matrices operate as blocking walls. The mask is adopted to expose the quantum dots and the PFA materials. Also, the developing process is applied to form the quantum dots/PFA layer 12 having the offset structure. Further, an etching process is adopted to remove the black matrix.

In step S14, coating a CF layer 13 on the quantum dots/PFA layer 12.

The CF layer 13 is coated on the quantum dots/PFA layer 12 having the offset structure. Wherein the CF layer 13 includes a red (R) photo-resist layer 131, a green (G) photo-resist layer 132, and a blue (B) photo-resist layer 133. The R photo-resist layer 131, the G photo-resist layer 132, and the B photo-resist layer 133 are formed to be above the quantum dots/PFA layer 12 and to be adjacent in turn. In addition, the thickness of the R photo-resist layer 131 is the same with the thickness of the gate (G), and the thickness of the B photo-resist layer 133 is larger than the thickness of the R photo-resist layer 131 and the G photo-resist layer 132 for 0.1-0.5 um. Correspondingly, the thickness of the quantum dots/PFA layer 12 corresponding to the R photo-resist layer 131 is the same with the thickness of the quantum dots/PFA layer 12 corresponding to the G photo-resist layer 132.

The thickness of the quantum dots/PFA layer 12 corresponding to the B photo-resist layer 133 is the smaller than the thickness of the quantum dots/PFA layer 12 corresponding to the G photo-resist layer 132 for 0.1-0.5 um.

In other embodiment, the location of the quantum dots/PFA layer 12 and the CF layer 13 may be switched, and the manufacturing method remains the same.

In step S15, forming a polarized layer 14 on the CF layer 13.

In step S16, forming an ITO layer 15 on the polarized layer 14.

In step S17, forming a PI layer 16 on the ITO layer 15.

Wherein the polarized layer 14, the ITO layer 15, and the PI layer 16 are formed by the common technology, and thus the detailed method is omitted hereinafter. At this moment, the manufacturing process of the CF substrate 1 is completed.

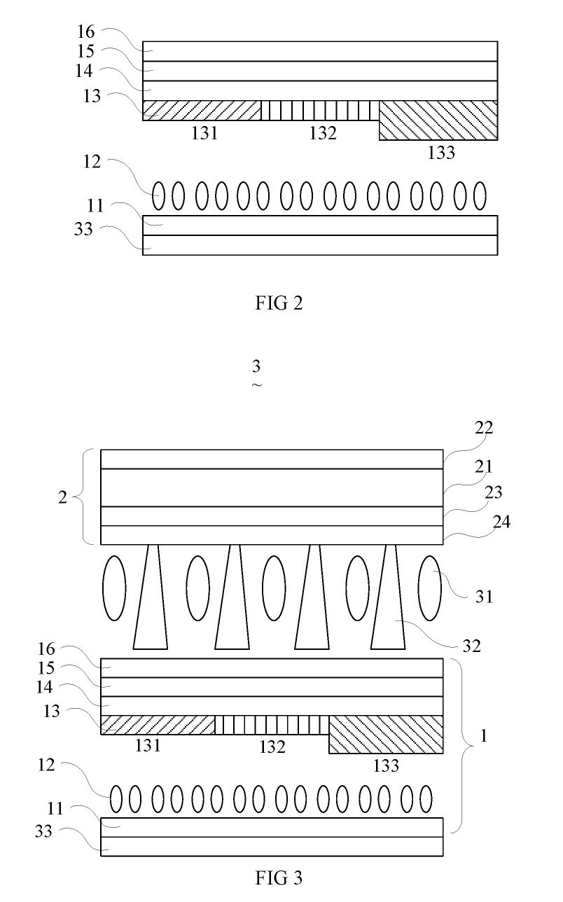

FIG. 2 is a schematic view of the CF substrate of FIG. 1. As shown in FIG. 2, the CF substrate 1 includes a substrate 11, a quantum dots/PFA layer 12 formed on the substrate 11, a CF layer 13 formed on the quantum dots/PFA layer 12, a polarized layer 14 formed on the CF layer 13, an ITO layer 15 formed on the polarized layer 14, and a PI layer 16 formed on the ITO layer 15. The quantum dots includes red (R), green (G), and blue (B) quantum dots. The R quantum dots, the G quantum dots, and the B quantum dots are mixed with the PFA materials. Afterward, the mixture is coated above the substrate. A yellow-light manufacturing process and the etching process are adopted to patternize the quantum dots and the PFA materials. The CF layer 13 includes a red (R) photo-resist layer 131, a green (G) photo-resist layer 132, and a blue (B) photo-resist layer 133. The R photo-resist layer 131, the G photo-resist layer 132, and the B photo-resist layer 133 are formed to be above the quantum dots/PFA layer 12 and to be adjacent in turn. Thus, by configuring the quantum dots/PFA layer 12 between the substrate 11 and the CF layer 13, the brightness of the backlight may be enhanced, and so do the color saturation and the color range of the liquid crystal panel.

The present disclosure also includes a LCD having the CF substrate 1 and a backlight module 33 and an array substrate 2. FIG. 3 is a schematic view of the LCD in accordance with one embodiment. As shown in FIG. 3, the LCD 3 includes a backlight module 33, the CF substrate 1, an array substrate 2, and liquid crystals 31 sealed between the CF substrate 1 and the array substrate 2.

In one embodiment, the CF substrate 1 of the LCD may be the CF substrate 1 in the above embodiments. The CF substrate 1 includes a first substrate 11, a quantum dots/PFA layer 12 formed on the first substrate 11, a CF layer 13 formed on the quantum dots/PFA layer 12, a polarized layer 14 formed on the CF layer 13, an ITO layer 15 formed on the polarized layer 14, and a PI layer 16 formed on the ITO layer 15. It is to be noted that the “first” is adopted to distinguish the substrate from the array substrate below.

The quantum dots of the quantum dots/PFA layer 12 of the CF substrate 1 include red (R), green (G), and blue (B) quantum dots. The R quantum dots, the G quantum dots, and the B quantum dots are mixed with the PFA materials. Afterward, the mixture is coated above the substrate. A yellow-light manufacturing process and the etching process are adopted to patternize the quantum dots and the PFA materials to form the quantum dots/PFA layer 12 having the offset structure. The CF layer 13 includes a red (R) photo-resist layer 131, a green (G) photo-resist layer 132, and a blue (B) photo-resist layer 133. The thickness of the R photo-resist layer 131 is the same with the thickness of the G photo-resist layer, and the thickness of the B photo-resist layer 133 is larger than the thickness of the R photo-resist layer 131 and the G photo-resist layer 132 for 0.1-0.5 um. The R photo-resist layer 131, the G photo-resist layer 132, and the B photo-resist layer 133 are formed to be above the quantum dots/PFA layer 12 and to be adjacent in turn.

The backlight module 33 is arranged on a surface of the CF substrate 1 facing away the array substrate 2.

The array substrate 2 includes a second substrate 21, a second polarized layer 22 formed on the second substrate 21, a second ITO layer 23 formed on the surface of the second substrate 21 facing away the second polarized layer 22, and a second PI layer 24 below the second ITO layer 23. The second polarized layer 22 may be a polarizer arranged on the surface of the array substrate 2 facing away the CF substrate 1.

The polarized layer 14 may be built-in, and is arranged on the surface of the CF substrate 1 facing toward the array substrate 2. Preferably, the CF layer 13 is a polarized layer adopting dye. The second polarized layer 22 may be built-in or may be configured externally. In the embodiment, the second polarized layer 22 is configured externally. The second polarized layer 22 is arranged on the surface of the array substrate 2 facing away the CF substrate 1. In addition, the polarized direction of the second polarized layer 22 is perpendicular to that of the polarized layer 14. The second ITO layer 23 is arranged on the surface of the array substrate 2 facing toward the CF substrate 1. The liquid crystals 31 are arranged between the second PI layer 24 and the PI layer 16. In addition, at least one photo-sensitive spacer 32 is arranged between the array substrate 2 and the CF substrate 1. The photo-sensitive spacer 32 is arranged within the liquid crystals 31 to maintain a cell distance between the array substrate 2 and the CF substrate 1.

In view of the above, when the backlight source is blue, the R quantum dots and the G quantum dots within the quantum dots/PFA layer 12 may emit light beams, mixed by red and green lights, having narrow width at half height when being activated by the blue backlight. The light beams are overlapped with the blue backlight to emit white light. When the backlight source is white, the R quantum dots, the G quantum dots, or the B quantum dots may be overlapped with the white light to emit the white light. Thus, by configuring the quantum dots/PFA layer 12 on the CF substrate, the brightness of the backlight may be enhanced. In addition, the power consumption and the cost may be saved so as to enhance the color saturation and the color range of the liquid crystal panel.

The above manufacturing method may be adopted to obtain the CF substrate 1, and may be assembled with the array substrate 2 by conventional process. Afterward, the liquid crystals 31 are filled within the cell to obtain the LCD 3 having the quantum dots/PFA layer 12.

In view of the above, by configuring the quantum dots/PFA layer on the CF substrate, the backlight brightness may be enhanced due to the characteristics of the quantum dots/PFA layer. In addition, the power consumption and the cost may be saved so as to enhance the color saturation and the color range of the liquid crystal panel.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A manufacturing method of color filter (CF) substrate, comprising:
providing a substrate;
mixing quantum dots with PFA material and coating the material on the substrate, wherein the quantum dots comprise red (R), green (G), and blue (B) quantum dots;
adopting a mask to expose the quantum dots and the PFA materials, and applying a developing process to obtain a quantum dots/PFA layer having an offset structure; and
coating a CF layer on the quantum dots/PFA layer, wherein the CF layer comprises a red (R) photo-resist layer, a green (G) photo-resist layer and a blue (B) photo-resist layer, and the R photo-resist layer, the G photo-resist layer, and the B photo-resist layer are formed to be above the quantum dots/PFA layer and to be adjacent in turn.

2. The manufacturing method claimed in claim 1, wherein a thickness of the R photo-resist layer is the same with the thickness of the G photo-resist layer, and the thickness of the B photo-resist layer is larger than the thickness of the R photo-resist layer or the G photo-resist layer for 0.1-0.5 um.

3. The manufacturing method claimed in claim 1, wherein after the step of coating a CF layer on the quantum dots/PFA layer, the method further comprises:
forming a polarized layer on the CF layer;
forming an ITO layer on the polarized layer; and
forming a PI layer on the ITO layer.

4. A CF substrate, comprising:
a substrate;
a quantum dots/PFA layer formed on the substrate;
a CF layer formed on the quantum dots/PFA layer; and
wherein the quantum dots comprise red (R), green (G), and blue (B) quantum dots, the CF layer comprises a red (R) photo-resist layer, a green (G) photo-resist layer and a blue (B) photo-resist layer, and the R photo-resist layer, the G photo-resist layer, and the B photo-resist layer are formed to be above the quantum dots/PFA layer and to be adjacent in turn.

5. The CF substrate claimed in claim 4, wherein a thickness of the R photo-resist layer is the same with the thickness of the G photo-resist layer, and the thickness of the B photo-resist layer is larger than the thickness of the R photo-resist layer or the G photo-resist layer for 0.1-0.5 um.

6. The CF substrate claimed in claim 4, wherein the CF substrate further comprises:
a polarized layer on the CF layer;
an ITO layer on the polarized layer; and
a PI layer on the ITO layer.

7. A liquid crystal device (LCD), comprising:
a CF substrate, an array substrate, a backlight module, and liquid crystals between the array substrate and the CF substrate, the CF substrate comprises:
a first substrate;
a quantum dots/PFA layer formed on the first substrate;
a CF layer formed on the quantum dots/PFA layer; and
wherein the quantum dots comprise red (R), green (G), and blue (B) quantum dots, the CF layer comprises a red (R) photo-resist layer, a green (G) photo-resist layer and a blue (B) photo-resist layer, and the R photo-resist layer, the G photo-resist layer, and the B photo-resist layer are formed to be above the quantum dots/PFA layer and to be adjacent in turn.

8. The LCD claimed in claim 7, wherein a thickness of the R photo-resist layer is the same with the thickness of the G photo-resist layer, and the thickness of the B photo-resist layer is larger than the thickness of the R photo-resist layer or the G photo-resist layer for 0.1-0.5 um.

9. The LCD claimed in claim 7, wherein the CF substrate further comprises:
a first polarized layer formed on the CF layer;
a first ITO layer formed on the first polarized layer; and
a first PI layer formed on the first ITO layer.

10. The LCD claimed in claim 9, wherein the array substrate further comprises:
a second substrate;
a second polarized layer formed on the second substrate;
a second ITO formed on a surface of the second substrate facing away the second polarized layer;
a second PI layer below the second ITO layer; and
the liquid crystals are arranged between the first PI layer and the second PI layer.
